(19) United States
(12) Patent Application Publication
(10) Pub. No.: US 2026/0264118 A1
(43) Pub. Date: Sep. 10, 2026

(54) FIXTURE FOR FLUSHING CONTAMINANTS FROM PEDESTALS

(71) Applicant: LAM RESEARCH CORPORATION, Fremont, CA (US)

(72) Inventors: Joe Victor CARPENTER, San Jose, CA (US); Andrew Paul EIB, Campbell, CA (US); Sudhir CHOPRA, San Jose, CA (US); Arvind RAJU, Bangalore (IN); Kyle CHENG, Milptas, CA (US)

(21) Appl. No.: 19/167,715

(22) PCT Filed: Mar. 26, 2024
(86) PCT No.: PCT/US2024/021509

§ 371 Date: Sep. 22, 2025

Related U.S. Application Data
(60) Provisional application No. 63/455,232, filed on Mar. 28, 2023.

(51) Int. Cl. B08B 9/032; H10P 72/76

(52) U.S. Cl. CPC B08B 9/0321; H10P 72/7624; B08B 2209/032

(57) ABSTRACT

A fixture for cleaning a pedestal of a substrate processing system includes first and second portions of the fixture, a plurality of fasteners, and an adapter. The first portion is configured to couple to a first surface of a base portion of the pedestal. The first portion includes a first port configured to fluidly connect with a plenum in the base portion of the pedestal. The second portion is configured to couple to a second surface of the base portion of the pedestal. The fasteners are configured to fasten the first and second portions of the fixture to clamp the base portion of the pedestal between the first and second portions of the fixture. The adapter is configured to couple to a conduit in a stem portion of the pedestal. The adapter includes a second port configured to fluidly connect with the plenum via the conduit.

### CROSS-REFERENCE TO RELATED APPLICATIONS

This application claims the benefit of U.S. Provisional Application No. 63/455,232, filed on Mar. 28, 2023. The entire disclosure of the application referenced above is incorporated herein by reference.

### FIELD

The present disclosure relates generally to substrate processing systems and more particularly to a fixture for flushing contaminants from pedestals used in substrate processing systems.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

Pedestals used to support substrates in substrate processing systems are manufactured by brazing various components. Brazing is a process used to join two or more metallic components by melting and flowing a filler metal into a joint of two components. The filler metal has a lower melting point than the metal components being joined. Brazing differs from welding since unlike welding, brazing does not involve melting the components being joined. Brazing also differs from soldering since brazing uses a higher temperature and is used to join much more closely fitted components than soldering. In brazing, the filler metal flows into a gap between close-fitting components by capillary action. The filler metal is heated slightly above the melting point of the filler metal in a suitable atmosphere (e.g., in presence of a chemical agent called a flux). The filler metal flows over the base metal component in a process called wetting and is cooled to join the components together. One advantage of brazing is the ability to join the same or different metals with considerable strength. However, residual brazing material remains deposited in crevices of the components even after thoroughly cleaning the brazed components.

### SUMMARY

A fixture for cleaning a pedestal of a substrate processing system comprises a first portion of the fixture, a second portion of the fixture, a plurality of fasteners, and an adapter. The first portion of the fixture is configured to couple to a first surface of a base portion of the pedestal. The first portion comprises a first port configured to fluidly connect with a plenum in the base portion of the pedestal. The second portion of the fixture is configured to couple to a second surface of the base portion of the pedestal. The plurality of fasteners is configured to fasten the first and second portions of the fixture to clamp the base portion of the pedestal between the first and second portions of the fixture. The adapter is configured to couple to a conduit in a stem portion of the pedestal. The adapter comprises a second port configured to fluidly connect with the plenum via the conduit.

In additional features, the first portion and the adapter are configured to circulate a cleaning fluid through the first and second ports and the plenum.

In additional features, the cleaning fluid comprises a mixture of acids.

In additional features, the first port is configured to receive a cleaning fluid that flows through the plenum and flows out of the second port.

In additional features, the second port is configured to receive a cleaning fluid that flows through the plenum and flows out of the first port.

In additional features, the fixture further comprises an annular gasket disposed between the first portion and the first surface of the base portion of the pedestal. The annular gasket is configured to seal areas on the first surface of the base portion of the pedestal that are radially inwards and outwards from the annular gasket.

In additional features, the adapter is configured to seal a second conduit in the stem portion of the pedestal provided to create vacuum on the first surface of the base portion of the pedestal.

In additional features, the first portion comprises a plate, a manifold, a plurality of conduits, and a gasket. The plate comprises a first surface and a second surface. The manifold is connected to the first surface of the plate and to the first port. The plurality of conduits is connected to the manifold. The gasket is disposed between the second surface of the plate and the first surface of the base portion of the pedestal.

In additional features, the plate comprises an annular groove on the second surface of the plate. The gasket is disposed in the annular groove. The plate and the gasket comprise a plurality of through holes that are aligned with each other and with a groove of the plenum on the first surface of the base portion of the pedestal. The plurality of conduits is connected to the plurality of through holes in the plate, respectively.

In additional features, the annular groove and the gasket comprise alignment features that align the plurality of through holes of the plate and the gasket.

In additional features, the gasket is configured to seal areas on the first surface of the base portion of the pedestal that are radially inwards and outwards from the gasket.

In additional features, the fixture further comprises a plurality of plugs configured to couple with a plurality of support structures provided on a periphery of the base portion of the pedestal to support a carrier ring. The plate comprises a plurality of protrusions extending radially from outer edges of the plate to an outer diameter of the gasket. The plurality of protrusions is configured to fit in the plurality of support structures, respectively. Radially inner ends of the plurality of protrusions position the plurality of plugs to contact the outer diameter of the gasket and to seal the plurality of support structures.

In additional features, the gasket comprises a plurality of pads that surrounds the plurality of through holes of the gasket, respectively; that extends over the plurality of plugs, respectively; and that extends radially inwards from an inner diameter of the gasket beyond an inner diameter of the groove of the plenum on the first surface of the base portion of the pedestal.

In additional features, the fixture further comprises a metal ring disposed on a periphery of the first surface of the plate. The plurality of fasteners pass through the metal ring.

In additional features, the plate comprises a plurality of feet attached to the first surface of the plate.

In additional features, the plate comprises a chemically resistant material.

In additional features, the second portion comprises an annular plate comprises an annular groove and a ridge. The annular groove is located on a first surface of the annular plate along an inner diameter of the annular plate. An outer diameter of the annular groove is greater an outer diameter of the base portion of the pedestal. An inner diameter of the annular groove is less than the outer diameter of the base portion of the pedestal. The ridge extends on the first surface of the annular plate from the outer diameter of the annular groove. The ridge comprises a plurality of through holes to receive the plurality of fasteners.

In additional features, the fixture further comprises a plurality of guiding structures on the ridge to receive a plurality of support structures provided on a periphery of the base portion of the pedestal to support a carrier ring.

In additional features, the fixture further comprises a metal ring disposed on a periphery of the second surface of the plate. The plurality of fasteners pass through the metal ring.

In additional features, the fixture further comprises a plurality of handles on a periphery of the plate.

In additional features, the plate comprises a plurality of feet attached to the second surface of the plate.

In additional features, the fixture further comprises a plurality of hooks attached to the second surface of the plate.

In additional features, the plate comprises a chemically resistant material.

In additional features, the adapter comprises a clamp, a first component, and a second component. The clamp clamps the conduit and a second conduit disposed in the stem portion of the pedestal. The first component comprises a first circular member configured to attach to the stem portion of the pedestal and a first cylindrical member that extends from the first circular member. The second component comprises a second circular member, a second cylindrical member, and a solid cylindrical member. The second cylindrical member extends from the second circular member and sealingly attaches to the first cylindrical member. The solid cylindrical member extends from the second circular member within the second cylindrical member to the clamp and seals the second conduit.

second cylindrical member the solid cylindrical member comprises a bore. The bore comprises a first end connected to the conduit in the clamp and a second end defining the second port.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1A shows an example of a substrate processing system;

FIG. 1B shows an example of a pedestal used to process substrates in the substrate processing system of FIG. 1A;

FIG. 2 shows a top view of the pedestal of FIG. 1B;

FIG. 3 shows a top view of a plenum in a base portion of the pedestal of FIG. 1B that is used to supply an edge gas during substrate processing;

FIGS. 4 and 5 show cross-sectional views of the plenum of FIG. 3;

FIG. 6 shows an example of a fixture used to clean the plenum of FIG. 3 according to the present disclosure;

FIG. 7 shows a top view of a top plate of an upper portion of the fixture of FIG. 6;

FIG. 8 shows a bottom view of the top plate of FIG. 7;

FIG. 9 shows a cross-sectional view of the top plate of FIG. 7;

FIG. 10 shows a top view of a gasket coupled to a bottom surface of the top plate of FIG. 7;

FIG. 11 shows a bottom view of the gasket of FIG. 10 that is coupled to a top surface of the pedestal of FIG. 1B;

FIG. 12 shows a top view of the pedestal with the gasket of FIGS. 10 and 11 and without the top plate of FIGS. 7-9;

FIG. 13 shows a partial cross-sectional view of a portion of the top view shown in FIG. 12;

FIG. 14 shows a top view of a bottom plate of the fixture of FIG. 6;

FIG. 15 shows a bottom view of the bottom plate of the fixture of FIG. 6;

FIG. 16 shows a cross-sectional view of the bottom plate of FIGS. 14 and 15;

FIG. 17 shows a cross-sectional view of a guiding structure on the bottom plate shown in FIG. 14;

FIG. 18 shows a top view of the top plate of the upper portion of the fixture of FIG. 6 comprising a manifold assembly and conduits for facilitating flow of cleaning fluid through the fixture and the pedestal shown in FIG. 6;

FIG. 19 shows a side view of the manifold assembly shown in FIG. 18; and FIG. 20 shows a cross-sectional view of an adapter coupled to a stem portion of the pedestal of FIG. 1B to facilitate flow of cleaning fluid through the fixture and the pedestal shown in FIG. 6.

In the drawings, reference numbers may be reused to identify similar and/or identical elements.

### DETAILED DESCRIPTION

A pedestal generally comprises a base portion and a stem portion made of a metal or an alloy or metallic materials. During processing, a substrate is placed on the base portion. The base portion comprises multiple metallic layers that are brazed. The pedestal comprises several channels that pass through the base and stem portions. For example, in pedestals that use vacuum clamping to clamp substrates during processing, a plenum and various channels are formed in the pedestal to effectuate vacuum clamping. The channels have small openings on a top surface of the base portion of the pedestal. The channels are connected to a conduit that passes through the stem portion of the pedestal. The conduit is connected to a vacuum pump that creates vacuum in the channels to clamp the substrate to the base portion of the pedestal.

In addition, some pedestals are designed to supply an edge gas (e.g., a purge gas or a tuning gas) that flows out through an upper periphery of the base portion, which surrounds edges of the substrate, to control processing (e.g., deposition or etching) at the edges of the substrate. These pedestals comprise a gas plenum and gas channels, which are separate from the plenum and the channels used for vacuum clamping, to supply the edge gas. The gas channels are connected to a gas conduit that also passes through the stem portion of the pedestal and that is connected to a gas supply that supplies the edge gas during substrate processing.

In brazed pedestals, excess filler material overflows into cavities such as the various plenums and channels inside the pedestal. Residual filler material in these cavities flakes off in the form of particles due to harsh thermal and chemical conditions prevailing in the processing chamber during substrate processing. The particles in the plenum and channels used for vacuum clamping flow downward and are removed by the vacuum pump and do not contaminate the processing chamber. However, the particles in the gas plenum and the gas channels used to supply the edge gas to the upper periphery of the base portion flow upward with the edge gas and are ejected into the processing chamber and contaminate the processing chamber. The contamination is highly undesirable in substrate processing.

The present disclosure provides a system and a method to remove the residual filler material from the cavities in the brazed pedestal to prevent contamination of the processing chamber during substrate processing. Specifically, the system comprises a fixture designed to supply an acid mixture through the gas conduit into and through the gas plenum and the gas channels used to supply the edge gas. The acid mixture etches and removes the residual filler material from the gas plenum and the gas channels. The fixture comprises a seal to protect the upper surface of the pedestal from the acid mixture. The fixture cleans the gas plenum and the gas channels without etching the upper surface of the pedestal. The acid mixture can comprise one or more acids and water other suitable dilutant. A non-limiting example of the acid mixture includes 2.5% HF, 0.7% HNO3, and 97.8% H2O by weight although other acids, dilutants, and concentrations may be used. For example, the acid mixture can comprise 0.25~5% HF, 1~5% HNO3, and balance H2O.

The acid mixture can be flushed through the pedestal in either direction—from the stem portion end to the base portion end or from the base portion end to the stem portion end. For example, the gas mixture can be supplied from the edge gas conduit end and can be collected at the base portion end. Alternatively, the gas mixture can be supplied from the base portion end and can be collected at the gas conduit end. After flushing the pedestal with the acid mixture, water is flushed through the pedestal (again, in either direction) to remove any remaining acid and particles. The fixture is described below in further detail.

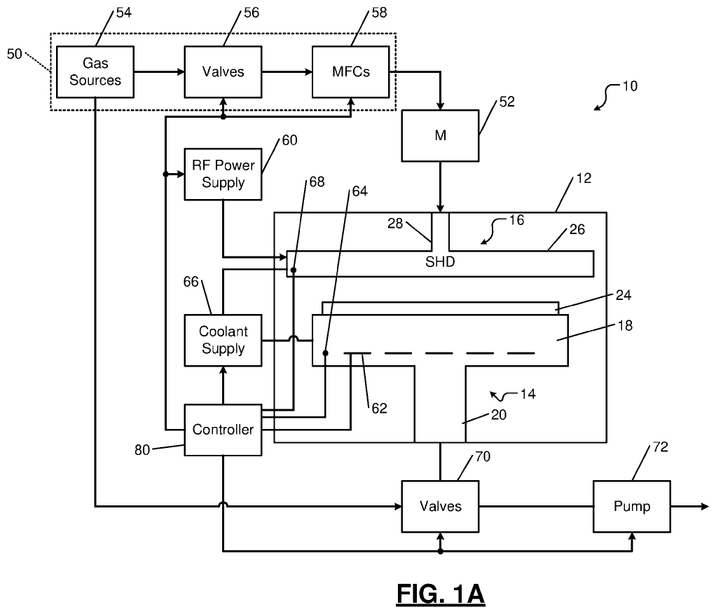

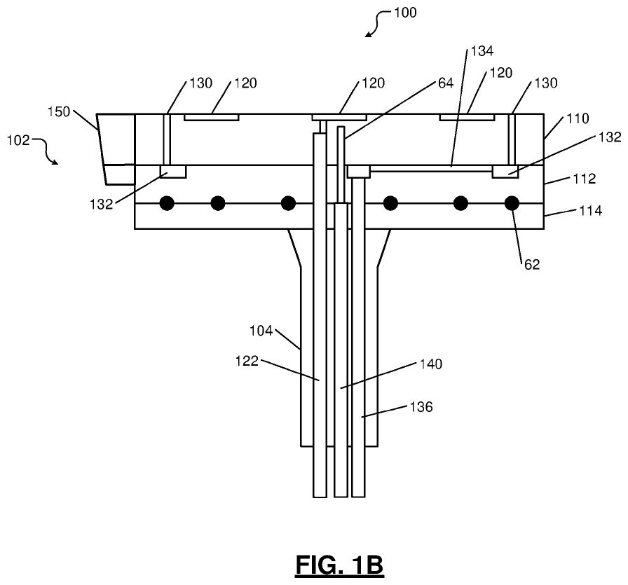

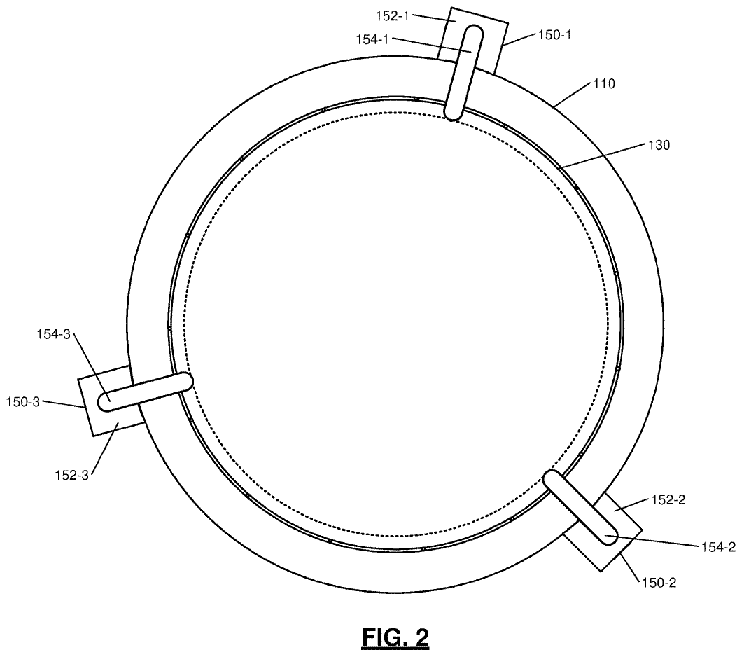

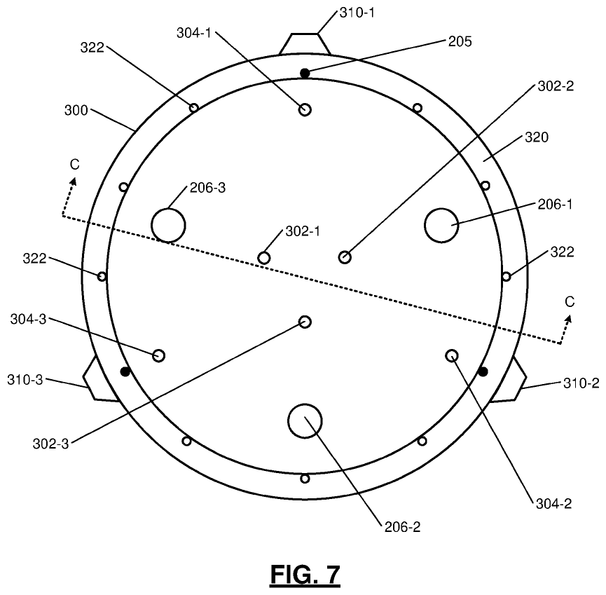

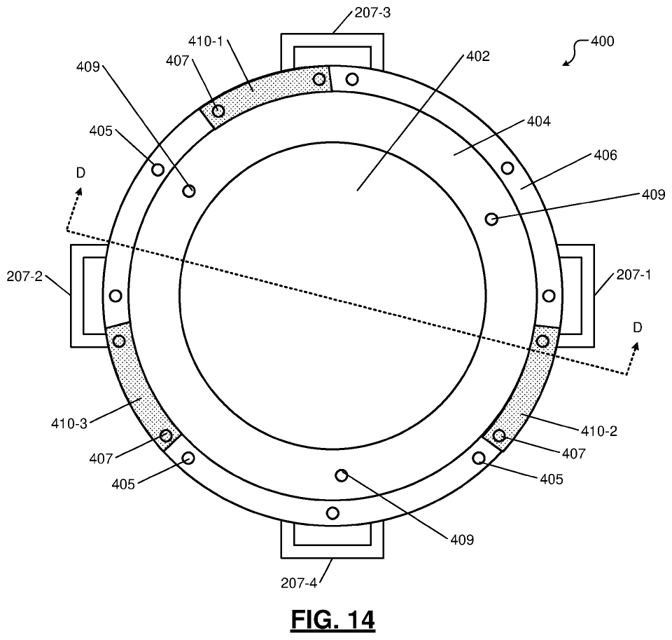

The present disclosure is organized as follows. FIGS. 1A and 1B show examples of a substrate processing system and a pedestal used in the substrate processing system. FIGS. 2-5 show examples of components of the pedestal that are cleaned and components of the pedestal that are protected by the fixture of the present disclosure. FIG. 6 schematically shows an example of the fixture. FIGS. 7-13 show various components of an upper portion of the fixture in further detail. FIGS. 14-20 show components of a lower portion of the fixture in further detail.

### Substrate Processing System

FIG. 1A shows an example of a substrate processing system 10. The substrate processing system 10 comprises a processing chamber 12. The processing chamber 12 comprises a pedestal 14 and a showerhead 16. The pedestal 14 comprises a base portion 18 and a stem portion 20. The stem portion 20 extends from base portion 18 and is coupled to the bottom of the processing chamber 12. The base portion 18 and the stem portion 20 comprise a metallic material. For example, the metallic material comprises aluminum, stainless steel, or an alloy of metallic materials. During processing, a substrate 24 is arranged on a top surface of the base portion 18 of the pedestal 14.

The showerhead 16 comprises a base portion 26 and a stem portion 28. The base portion 26 of the showerhead 16 is cylindrical. The base portion 26 of the showerhead 16 is greater in diameter than the substrate 24 and the base portion 18 of the pedestal 14. The stem portion 28 of the showerhead 16 extends from the base portion 26 of the showerhead 16. The stem portion 28 of the showerhead 16 is attached to a top plate of the processing chamber 12. The stem portion 28 of the showerhead 16 receives various gases (e.g., process gases, cleaning gases, etc.) from a gas delivery system 50 via a manifold 52. The base portion 26 of the showerhead 16 comprises a faceplate comprising through holes or slots (not shown) through which the gases are introduced into the processing chamber 12.

The substrate processing system 10 comprises the gas delivery system 50. The gas delivery system 50 comprises gas sources 54, valves 56, and mass flow controllers (MFCs) 58. The gas sources 54 supply various gases such as process gases, inert gases (also called purge gases, edge gases, carrier gases), cleaning gases, etc. The valves 56 are connected to the gas sources 54 and can be controlled to supply the gases to the MFCs 58. The MFCs 58 regulate the flow of gases to the manifold 52. The manifold supplies the gases or gas mixtures to the showerhead 16.

The substrate processing system 10 comprises a radio frequency (RF) power supply 60. The RF power supply supplies RF power to the showerhead 16 during processing of the substrate 24 and during cleaning of the processing chamber 12. The RF power excites the gases (e.g., process gases, cleaning gases) introduced into the processing chamber 12 to generate plasma between the showerhead 16 and the pedestal 14.

The base portion 18 of the pedestal 14 comprises a heater 62. The heater 62 heats the base portion 18 of the pedestal 14, which in turn heats the substrate 24. The base portion 18 of the pedestal 14 comprises a temperature sensor 64 to sense the temperature of the pedestal 14. The base portion 18 of the pedestal 14 also comprises cooling channels (not shown). A coolant supply 66 supplies a coolant to the cooling channels in the base portion 18 of the pedestal 14 to control the temperature of the pedestal 14.

The base portion 26 of the showerhead 16 may also comprise a heater (not shown) to heat the gases being introduced into the processing chamber 12. The base portion 26 of the showerhead 16 comprises a temperature sensor 68 to sense the temperature of the showerhead 16. The base portion 26 of the showerhead 16 also comprises cooling channels (not shown). The coolant supply 66 supplies the coolant to the cooling channels in the base portion 26 of the showerhead 16 to control the temperature of the showerhead 16.

The substrate processing system 10 comprises another set of valves 70. An edge gas from one of the gas sources 54 is introduced into the pedestal 14 via one of the valves 70. The edge gas flows around the edges of the substrate 24 to control processing (e.g., deposition, etching) at the edges (bevel) of the substrate 24. A vacuum pump 72 is connected to the pedestal 14 via another one of the valves 70. To clamp the substrate 24, the vacuum pump 72 creates vacuum on the top surface of the base portion 18 of the pedestal 14.

Alternatively, while not shown, the pedestal 14 may use other type of support mechanisms to support the substrate 24. For example, the substrate 24 may be supported by mesas disposed on the top surface of the base portion 18 of the pedestal 14. Mesas are tiny protrusions, also called minimum contact areas (MCAs), that can be of different shapes (e.g., cylindrical or polygonal). Regardless of the schemes used to support the substrate 24, the base portion 18 of the pedestal 14 can supply the edge gas that flows around the edges of the substrate 24 to control processing (e.g., deposition, etching) at the edges (bevel) of the substrate 24.

The substrate processing system 10 comprises a controller 80. The controller 80 controls the valves 56 and 70, the MFCs 58, the heaters in the pedestal 14 and the showerhead 16, the RF power supply 60, the supply of the coolant from the coolant supply 66 to the pedestal 14 and the showerhead 16, and the vacuum pump 72. The controller 80 monitors the temperatures of the pedestal 14 and the showerhead 16 using the temperature sensors 64 and 68 in the pedestal 14 and the showerhead 16. The controller 80 controls the temperatures of the pedestal 14 and the showerhead 16, by controlling the heaters in the pedestal 14 and the showerhead 16 and by controlling the supply of the coolant from the coolant supply 66 to the pedestal 14 and the showerhead 16.

### Pedestal

FIG. 1B shows an example of a pedestal 100 comprising a metallic material such as aluminum, stainless steel, or an alloy of metallic materials. The pedestal 100 shows the pedestal 14 of FIG. 1A in further detail. The pedestal 100 can be used in the processing chamber 12 in place of the pedestal 14 shown in FIG. 1A. The pedestal 100 comprises a base portion 102 and a stem portion 104. For example, the base portion 102 comprises three cylindrical plates 110, 112, 114. The plates 110, 112, 114 comprise the metallic material. The plates 110, 112, 114 are brazed together to form the base portion 102 of the pedestal 100.

In the base portion 102 of the pedestal 100, the plate 110 comprises grooves 120 on a top surface of the plate 110. The grooves 120 are annular. The grooves 120 are interconnected by radially extending grooves (not shown). A conduit 122 extends through the stem portion 104 of the pedestal 100, passes through the plates 114, 112, and 110, and is connected to the groove 120 near the center of the plate 110. The conduit 122 is connected to the vacuum pump 72 (shown in FIG. 1A). The vacuum pump 72 creates vacuum through the annular and radial grooves to clamp the substrate 24 to the top surface of the plate 110.

The plate 110 also comprises an annular groove 130 along the outer periphery of the top surface of the plate 110. The groove 130 is not in fluid communication with the grooves 120. The plate 112 comprises grooves 132 and 134 that are connected to each other and that are in fluid communication with the groove 130 in the plate 110. A conduit 136 extends through the stem portion 104 of the pedestal 100, passes through the plates 114 and 112, and is connected to the groove 134 near the center of the plate 112. The conduit 136 supplies the edge gas through the grooves 134, 132, 130 to control processing around edges of the substrate 24.

The base portion 102 of the pedestal 100 also comprises a plurality of support structures 150-1, 150-2, 150-3 (shown in FIG. 2, only one of the support structures is shown at 152 in FIG. 1B, collectively support structures 150) around the periphery of the base portion 102. The support structures 150 support a carrier ring (not shown) used to transfer the substrate 24 in and out of the processing chamber 12. The support structures 150 are shown and described below in further detail with reference to FIG. 2.

A heater (e.g., the heater 62 shown in FIG. 1A) is disposed between the plates 112 and 114. A temperature sensor (e.g., the temperature sensor 64 shown in FIG. 1A) is disposed in the plate 110 (or can be disposed in the plate 112 instead). A conduit extends through the stem portion 104 of the pedestal 100 and passes through the plate 114. Electrical connections to various components of the pedestal 100 such as the heater 62 and the temperature sensor 64 are provided through the conduit. The electrical connections are connected to the controller 80 (shown in FIG. 1A).

As described above, the plates 110, 112, and 114 are made of a metallic material and are brazed to form the base portion 102 of the pedestal 100. Residual filler material used in the brazing process remains in the grooves 134, 132, 130. The residual filler material deteriorates (e.g., corrodes, flakes) and forms particles over time due to harsh thermal and chemical environment used in different processes performed in the processing chamber 12 (shown in FIG. 1A). The particles then eject into the processing chamber when the edge gas is supplied through grooves 134, 132, 130, which contaminates the processing chamber 12.

A fixture used to clean and remove the residual filler material from the pedestal 100 according to the present disclosure is shown and described below with reference to FIG. 6. Before describing the fixture in detail, a top view of the pedestal 100 showing the groove 130 and a plenum provided in the base portion 102 of the pedestal 100 to supply the edge gas are shown and described with reference to FIGS. 2-5.

### Pedestal Components Cleaned and Protected By Fixture

FIG. 2 shows the top view of the pedestal 100. In the view shown, only a top surface of the base portion 102 (a top view of the plate 110) of the pedestal 100 is visible. The vacuum clamping area on the top surface of the plate 110 of the base portion 102, including the grooves 120 used for clamping, is enclosed in a dotted circle and is not shown in detail. The groove 130 through which the edge gas is ejected around the edges of the substrate 24 is shown.

The base portion 102 of pedestal 100 comprises the support structures 150 to support a carrier ring (not shown). Each support structure 150 comprises a slot 152 and a groove 154 that extends into a periphery of the plate 110. The slots of the support structures 150 are shown at 152-1, 152-2, 152-3 (collectively the slots 152). The grooves of the support structures 150 are shown at 154-1, 154-2, 154-3 (collectively the grooves 154).

The grooves 154 intersect the groove 130 on the plate 110 through which the edge gas is ejected around the edges of the substrate 24. The fixture 200 shown in FIG. 6 provides features (described below in detail) that cover the grooves 154 during the cleaning process. Due to these features, the cleaning fluid does not flow into the vacuum clamping area enclosed in the dotted circle and does not harm the top surface of the plate 110, which includes the grooves 120 for vacuum clamping or mesas to support the substrate 24.

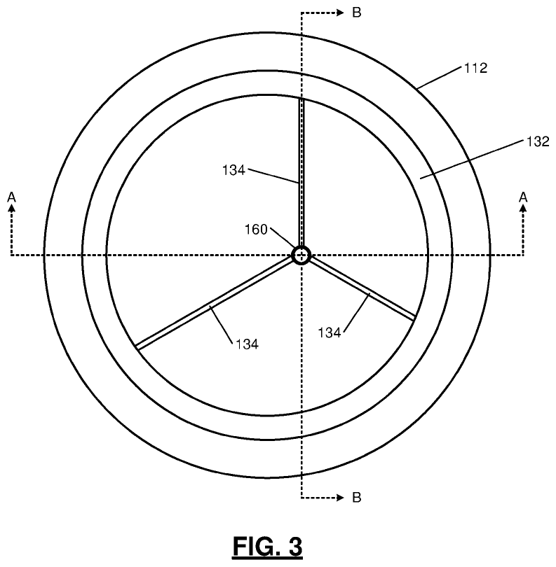

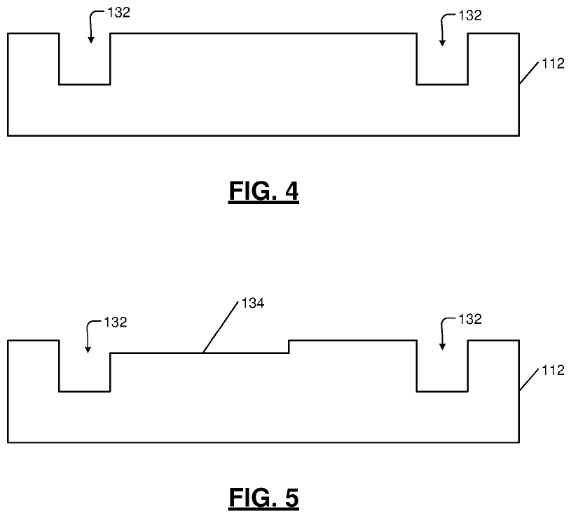

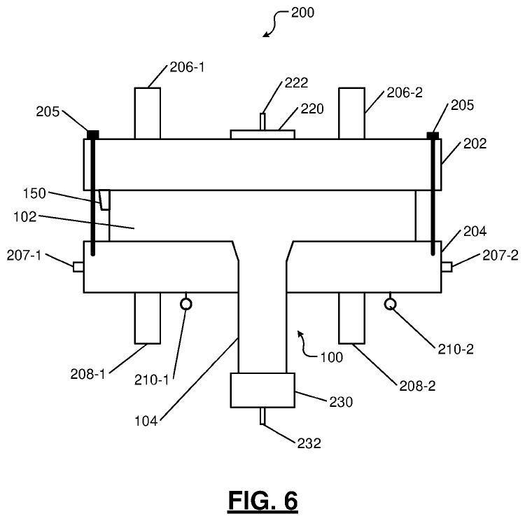

FIG. 3 shows an example of a top view of the plate 112. The top view of the plate 112 shows an example of a plenum and grooves in the plate 112 of the base portion 102 of the pedestal 100. The plenum and the grooves are used to supply the edge gas from the conduit 136 to the groove 130. The plate 112 comprises the grooves 132 and 134. Examples of cross-sectional views of the grooves 134, 132 are shown in FIGS. 4 and 5. When the base portion 102 is formed by brazing the plates 110, 112, 114, a bottom surface of the plate 110 is brazed to a top surface of the plate 112. The bottom surface of the plate 110 and the grooves 132 and 134 define a plenum in the plate 112 through which the edge gas flows as follows.

The plate 112 comprises a hole 160 near the center of the plate 112. The conduit 136 (shown in FIG. 1B) is connected to the hole 160. The edge gas from the conduit 136 flows through the hole 160 into the grooves 134. The grooves 134 extend radially and are connected to the groove 132, which is annular. While only three grooves 134 are shown for example only, any number of grooves 134 can be used. Further, while the grooves 134 are shown as being radial, the grooves 134 can have other shapes.

The edge gas from the conduit 136 and the hole 160 flows through grooves 134 into the groove 132. As shown in FIG. 1B, the plate 110 comprises the groove 130, which is also annular, and which is in fluid communication with the groove 132 in the plate 112. The edge gas flows from the groove 132 into the groove 130 and is ejected from the groove 130 around the substrate 24. In some examples, the edge can also flow under the substrate 24 to prevent processing (e.g., deposition, etching) on the backside of (i.e., under) the substrate 24.

During brazing of the plates 110, 112, residual filler material remains in the grooves 134, 132, 130. The residual filler material can deteriorate over time due to the harsh thermal and chemical environment that prevails in the processing chamber 12. The deteriorated filler material forms particles that get ejected with the flow of the edge gas, which contaminates the processing chamber 12. The fixture described below with reference to FIG. 6 cleans and removes the residual filler material from the 134, 132, 130. Accordingly, the contamination of the processing chamber 12 is prevented.

FIGS. 4 and 5 show examples of cross-sectional views of the plate 112 taken along lines A-A and B-B shown in FIG. 3. The cross-sectional views of the plate 112 show examples of the grooves 134 and 132.

### Fixture

FIG. 6 shows an example of the fixture 200 used to clean the pedestal 100 according to the present disclosure. The fixture 200 mainly comprises an upper portion and a lower portion. The upper and lower portions of the fixture 200 can also be called first and second portions, respectively. Each of the upper and lower portions of the fixture 200 comprises various components that are shown and described in further detail with reference to FIGS. 7-20. FIG. 6 schematically shows a side view of the fixture 200 in which only side views of some of the components of the fixture 200 are visible. Various views of these components are shown and described in further detail with reference to FIG. 7 onwards.

As described below, the fixture 200 can clean the pedestal 100 by supplying a cleaning fluid from either direction: from stem portion 104 to base portion 102 (in the direction of the flow of the edge gas) or from the base portion 102 to the stem portion 104. FIG. 6 shows the fixture 200 attached to the pedestal 100 with the pedestal 100 in upright position with the base portion 102 on top and the stem portion 104 at the bottom, which is the normal position in which the pedestal 100 is used in the processing chamber 12. The fixture 200 and the pedestal 100 can be used in the positions shown in FIG. 6 when the cleaning fluid is supplied from the top of the fixture 200 (i.e., through the base portion 102 of the pedestal 100) and is collected at the bottom of the fixture 200 (i.e., through the stem portion 104 of the pedestal 100).

Alternatively, the entire assembly comprising the pedestal 100 and the fixture 200 shown in FIG. 6 can be inverted or turned upside down (i.e., rotated by 180 degrees compared to the orientation shown in FIG. 6). In the rotated or inverted position, the stem portion 104 of the pedestal 100 is at the top, the base portion 102 of the pedestal is at the bottom, and the top and bottom portions of the fixture become the bottom and top portions, respectively.

Throughout the present disclosure, all references to top, bottom, and side views; top and bottom sides; upper and lower sides; top and bottom portions; upper and lower portions; top and bottom surfaces; upper and lower surfaces; top and bottom regions; upper and lower regions; etc. of various components and assemblies presume that the fixture 200 and the pedestal 100 are in the orientation shown in FIG. 6.

In FIG. 6, the fixture 200 comprises an upper portion 202 and a lower portion 204. For directional neutrality, the upper and lower portions 202 of the fixture 200 can also be called first and second portions, respectively. The upper portion 202 of the fixture 200 is coupled to the top surface of the base portion 102 (i.e., the top surface of the plate 110) of the pedestal 100. The lower portion 204 of the fixture 200 is coupled to the bottom surface of the base portion 102 (i.e., to the bottom surface of the plate 114) of the pedestal 100.

The upper and lower portions 202, 204 of the fixture 200 have diameters (or outer dimensions) greater than the diameter of the base portion 102 of the pedestal 100. The upper and lower portions 202, 204 of the fixture 200 extend radially beyond the support structures 150 of the base portion 102 of the pedestal 100. A plurality of fasteners 205 are used to fasten the upper and lower portions 202, 204 of the fixture 200. When fastened, the pedestal 100 is clamped (sandwiched) between the upper and lower portions 202, 204 of the fixture 200.

The upper portion 202 of the fixture 200 comprises feet 206-1, 206-2, 206-3 (foot 206-3 not visible in the view shown, collectively the feet 206). While three feet 206 are shown for example only, the upper portion 202 of the fixture 200 can comprise additional feet. The feet 206 are fastened to the upper portion 202 of the fixture 200. When the fixture 200 with the pedestal 100 clamped in the fixture 200 is inverted to perform the cleaning process, the fixture 200 with the pedestal 100 clamped in the fixture 200 rests on the feet 206 of the upper portion 202 of the fixture 200.

The lower portion 204 of the fixture 200 comprises feet 208-1, 208-2, 208-3 (foot 208-3 not visible in the view shown, collectively the feet 208). While three feet 208 are shown for example only, the lower portion 204 of the fixture 200 can comprise additional feet. The feet 208 provide stability while mounting the pedestal 100 onto the lower portion 204 of the fixture 200.

The lower portion 204 of the fixture 200 comprises handles 207-1, 207-2 (and handles 207-3, 207-4 not visible in the view shown, collectively the handles 207). The handles are attached to the side of the lower portion 204 of the fixture 200. The handles 207 help in moving the fixture 200 around once the pedestal 100 is clamped inside the fixture 200.

The lower portion 204 additionally comprises hooks or similar structures shown at 210-1, 210-2 (and at least one additional hook 210-3, collectively the hooks 210). The hooks 210 are attached to a gantry (not shown). The gantry is used to transport the assembly comprising the fixture 200 with the pedestal 100 clamped inside the fixture 200. Using the gantry, the assembly is transported in an inverted position to a cleaning site. Once situated at the cleaning site, the assembly (i.e., the fixture 200 with the pedestal 100 clamped inside the fixture 100 and with the assembly in the inverted position) rests on the feet 206 of the upper portion 202 of the fixture 200. At this point, the fixture 200 is ready to clean the pedestal 100 as described below in detail.

To clean the pedestal 100, the fixture 200 comprises a manifold assembly 220 attached to the upper portion 202 of the fixture 200. The manifold assembly 220 is shown and described below in detail. Briefly, the manifold assembly 220 comprises an inlet 222. Depending on whether the cleaning fluid is supplied to the fixture 200 from the upper portion 202 or the bottom portion 204 of the fixture 200, the inlet 222 can also be called an outlet. A plurality of conduits (shown at 370 in subsequent figures) extend from the manifold assembly 220. As shown and described below in detail with reference to subsequent figures, the conduits are attached to components inside the upper portion 202 of the fixture 200. These components in the upper portion 202 of the fixture 200 fluidly connect the conduits to the groove 130 in the pedestal 100 that is used to supply the edge gas as described above.

As explained below in further detail, the upper portion 202 of the fixture 200 comprises additional features and components that fit into (couple with) the grooves 154 in the support structures 150 of the base portion 102 of the pedestal 100. These features and components are designed to direct and maintain the flow of the cleaning fluid only through the groove 130 in the base portion 102 of the pedestal 100 and to prevent the cleaning fluid from flowing over to the upper surface of the pedestal 100 (i.e., over the upper surface of the plate 110 of the pedestal) where grooves 120 for vacuum clamping or mesas are provided.

Additionally, to clean the pedestal 100, the fixture 200 comprises an adapter (a coupling assembly) 230 attached to the stem portion 104 of the pedestal 100 near the lower portion 204 of the fixture 200. The adapter 230 is shown and described below in detail. Briefly, the adapter 230 comprises an inlet 232. Again, depending on whether the cleaning fluid is supplied to the fixture 200 from the upper portion 202 or the bottom portion 204 of the fixture 200, the inlet 232 can also be called an outlet 232. For directional neutrality, the inlets/outlets 222 and 232 of the manifold assembly 220 and the adapter 230 can also be called first and second ports, respectively. As shown and described below in detail with reference to subsequent figures, the adapter 230 couples the conduit 136 to the inlet 232. The adapter 230 blocks (seals) conduit 122 used for vacuum clamping. The adapter 230 prevents the cleaning fluid from entering the conduit 122 used for vacuum clamping.

In use, with the assembly of the fixture 200 with the pedestal 100 clamped in the fixture 200 in inverted position, the cleaning fluid is supplied through the inlet 232 (the second port) and the adapter 230. The cleaning fluid flows through the conduit 136; through the grooves 134, 132, 130 in the base portion 102 of the pedestal 100; through the conduits attached to the upper portion 202 of the fixture 200; through the manifold assembly 220; and flows out via the outlet 222 (the first port). Alternatively, with the assembly in the orientation shown in FIG. 6, the cleaning fluid can be supplied through the inlet 222 (the first port) and the manifold assembly 220. The cleaning fluid flows through the conduits attached to the manifold assembly 220 and the upper portion 202 of the fixture 200; through the grooves 134,132, 130 in the base portion 102 of the pedestal 100; through the conduit 136; through the adapter 230; flows out via the outlet 232 (the second port).

Regardless of the direction in which the cleaning fluid is supplied and circulated through the fixture 200 and the pedestal 100, the cleaning fluid cleans the grooves 134,132, 130 in the base portion 102 of the pedestal 100. The cleaning fluid removes the residual filler material from the grooves 134,132, 130 in the base portion 102 of the pedestal 100. After the pedestal 100 is cleaned as described above after the pedestal 100 is manufactured, when the edge gas is supplied through the conduit 136, no particles are formed due to deterioration of residual filler material in these grooves, no particles are ejected into the processing chamber 12 with the flow of the edge gas, and contamination of the processing chamber is prevented.

While not shown, the fixture 200 can receive the cleaning fluid from a source of the cleaning fluid and the cleaning fluid exiting the fixture 200 can be collected in a reservoir. For example, the source of the cleaning fluid can be connected to the first port (element 222) of the fixture 200 and the reservoir can be connected to the second port (element 232) of the fixture 200. The cleaning fluid enters the fixture 200 though the first port (element 222), cleans the pedestal 100, exits the fixture 200 via the second port (element 232), and accumulates in the reservoir. Alternatively, the source of the cleaning fluid can be connected to the second port (element 232) of the fixture 200 and the reservoir can be connected to the first port (element 222) of the fixture 200. The cleaning fluid enters the fixture 200 though the second port (element 232), cleans the pedestal 100, exits the fixture 200 via the first port (element 222), and accumulates in the reservoir.

The fixture 200 is now described in further detail. FIGS. 7-13 show various components of the upper portion 202 of the fixture 200 in further detail. FIGS. 14-20 show components of the lower portion 204 of the fixture 200 in further detail. The sequence of assembling the components of the fixture 200 described in FIGS. 7-20 is described after the description of FIGS. 7-20.

### Upper Portion of Fixture

The upper portion 202 of the fixture 200 comprises a top plate 300, which is shown and described in detail with reference to FIGS. 7-9 and 13, and a gasket 350, which is shown and described in detail with reference to FIGS. 10, 11, and 13.

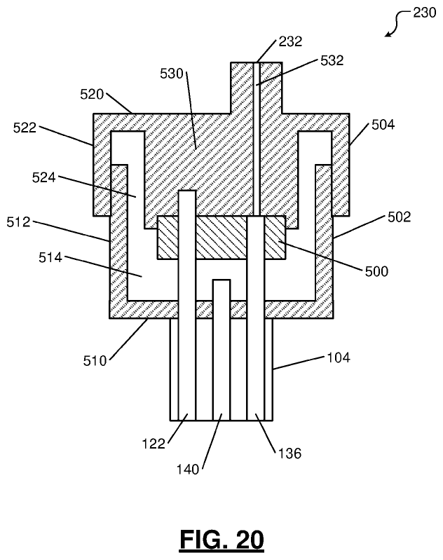

FIG. 7 shows an example of a top view of the top plate 300. The manifold assembly 220 and the conduits on the top plate 300 are omitted in this view to show other features of the top plate 300. The manifold assembly 220 and the conduits are shown and described in detail with reference to FIGS. 18 and 19.

In FIG. 7, the top plate 300 comprises a non-metallic material such as high-density polyethylene (HDPE). The material is resistant to corrosion from various acids and other chemicals that can be used in the cleaning fluid. The material also does not damage (e.g., scratch or mar) the top surface of the pedestal 100.

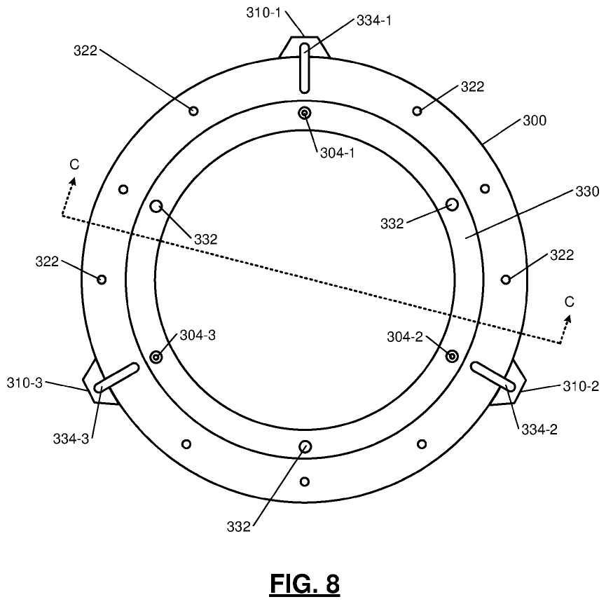

The top plate 300 comprises a plurality of holes 302-1, 302-2, 302-3 (collectively the holes 302) near the center of the top plate 300 to mount the manifold assembly 220 (shown in FIG. 18) on the top surface of the top plate 300. The top plate 300 comprises a plurality of holes 304-1, 304-2, 304-3 (collectively the holes 304) near the periphery of the top plate 300. A plurality of conduits (e.g., tubes, shown at 370 in FIG. 18) are connected to the manifold assembly 220 and to the holes 304 to facilitate the flow of the cleaning fluid. The holes 304 align with the groove 130 (shown in FIG. 8) to facilitate the flow of the cleaning fluid into the groove 130.

The feet 206 are attached to the top surface of the top plate 300. The feet 206 comprise a non-metallic material such as polyetheretherketone (PEEK), which is chemically resistant and which has mechanical strength to withstand the weight of the fixture 200 and the pedestal 100 when the assembly is inverted and the pedestal 100 is cleaned.

A diameter of the top plate 300 is greater than an outer diameter of the base portion 102 of the pedestal 100. The top plate 300 comprises a plurality of sealing fixtures 310-1, 310-2, 310-3 (collectively the sealing fixtures 310) at the periphery of the top plate 300. The sealing fixtures 310 are described in further detail with reference to FIGS. 8 and 13. Briefly, the sealing fixtures 310 extend radially outwards from outer edges of the top plate 300. The sealing fixtures 310 are integral to the top plate 300. The sealing fixtures 310 comprise the same material as the top plate 300. The shape of the sealing fixtures 310 conforms to the shape of the support structures 150 of the pedestal 100 (shown in FIG. 2). The sealing fixtures 310 comprise features at the bottom (shown in FIG. 8) that engage with and seal the support structures 150 of the pedestal 100. In pedestals that do not comprise the support structures 150, the sealing fixtures 310 can be omitted.

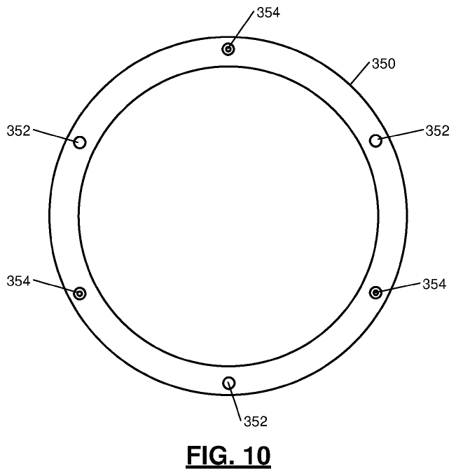

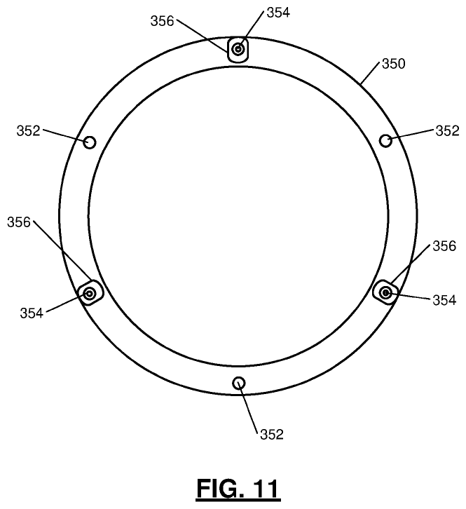

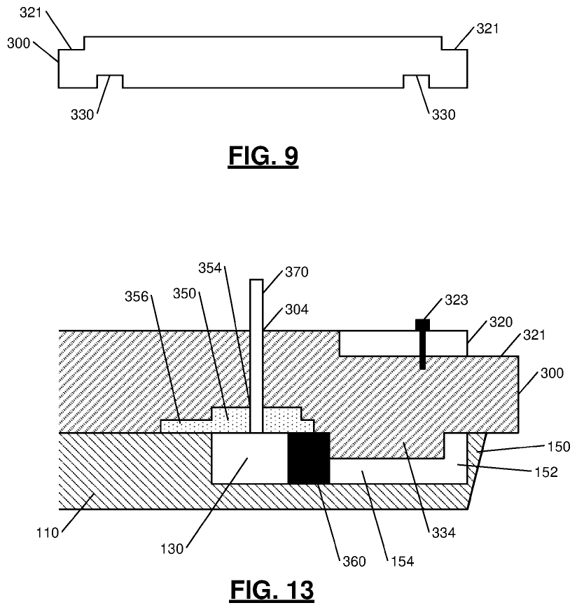

A metal ring (e.g., stainless steel ring) 320 is attached to the top surface of the top plate 300. The top surface of the top plate 300 comprises a groove 321 (shown in FIG. 9) in which the metal ring 320 is installed. The metal ring 320 and the top plate 300 comprise through holes 322. The fasteners 205 (shown in FIG. 6) are inserted into the through holes 322 to clamp the upper and lower portions 202, 204 of the fixture 200. The metal ring 320 helps in distributing load and improving load handling capacity of the assembly when the pedestal 100 is clamped in the fixture 200.

FIG. 8 shows an example of a bottom view of the top plate 300. Elements shown in FIG. 8 that are already described above are not described again for brevity. The bottom surface of the top plate 300 comprises a groove 330. The gasket 350 is installed in the groove 330 as described below with reference to FIGS. 10 and 11. The groove 330 comprises a plurality of alignment features 332 for aligning with corresponding aligning features on the gasket 350 (shown in FIGS. 10 and 11) when the gasket 350 is installed in the groove 330.

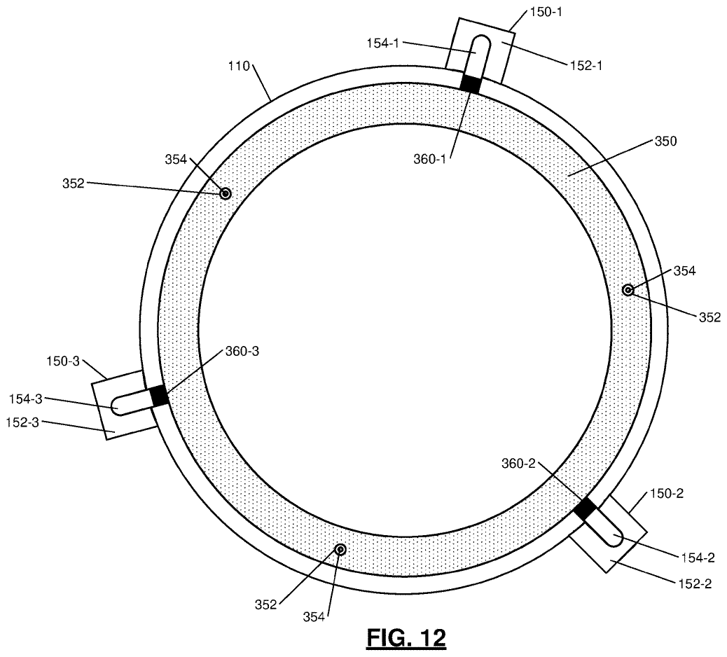

At the bottom surface of the sealing fixtures 310, the bottom surface of the top plate 300 comprises protrusions 334 (shown at 334-1, 334-2, 334-3, collectively the protrusions 334) that extend radially between the outer edges of the groove 330 and the outer edges of the sealing fixtures 310. With reference to the gasket 350, the protrusions 334 extend radially between the outer edges of the top plate 300 and an outer diameter of the gasket 350. The shape of the protrusions 334 conforms to the shape of the grooves 154 of the support structures 150 of the pedestal 100 (shown in FIG. 2). When the top plate 300 is installed on the top surface of the base portion 102 of the pedestal 100, the bottom surface of the top plate 300 engages with the top surface of the base portion 102 of the pedestal 100. The protrusions 334 engage with the grooves 154 of the support structures 150 of the pedestal 100. The grooves 154 and plugs (shown at 360 in FIG. 13) seal the support structures 150 of the pedestal 100 from the cleaning fluid as described in further detail with reference to FIGS. 12 and 13.

FIG. 9 shows a cross-sectional view of the top plate 300 taken along the line C-C shown in FIGS. 7 and 8. The view is shown with the top surface of the top plate 300 on top and the bottom surface of the top plate 300 on the bottom. Since the elements of the top plate 300 shown in FIG. 9 are already described above, they are not described again for brevity.

FIGS. 10 and 11 show examples of top and bottom views of the gasket 350, respectively. The gasket 350 is annular. An outer diameter of the gasket 350 is greater than an outer diameter of the groove 130 on the top surface of the base portion 102 of the pedestal 100 (shown in FIGS. 2, 12, and 13). The outer diameter of the gasket 350 is less than outer diameters of the top plate 300 and the base portion 102 of the pedestal 100. An inner diameter of the gasket 350 is less than an inner diameter of the groove 130 on the top surface of the base portion 102 of the pedestal 100 (shown in FIGS. 2, 12, and 13).

The gasket 350 comprises a non-metallic and flexible material such as a fluoro-elastomer. The top surface of the gasket 350 is attached to the bottom surface of the top plate 300. The top surface of the gasket 350 is press fit into the groove 330 in the bottom side of the top plate 300. The top surface of the gasket 350 comprises aligning features 352. When the top surface of the gasket 350 is attached to the bottom surface of the top plate 300, the aligning features 352 on the top surface of the gasket 350 are aligned with the alignment features 332 in the groove 330 on the bottom surface of the top plate 300.

The gasket 350 comprises a plurality of through holes 354. When the gasket 350 is attached to the top plate 300 as described above, the through holes 354 of the gasket 350 are aligned with the holes 304 in the top plate 300. The alignment features 332 in the groove 330 and the aligning features 352 on the top surface of the gasket 350 ensure that the through holes 354 of the gasket 350 are aligned with the holes 304 in the top plate 300. The through holes 354 facilitate the flow of the cleaning fluid between the holes 304 in the top plate 300 and the groove 130.

When the top plate 300 and the gasket 350 are installed on the top surface of the base portion 102 of the pedestal 100, the bottom surface of the gasket 350 covers and seals the groove 130 on the top surface of the base portion 102 of the pedestal 100. The gasket 350 prevents the cleaning fluid from flowing over the remainder of the top surface of the base portion 102 of the pedestal 100 (e.g., area covered by the dotted circle shown in FIG. 3). The seal provided by the gasket 350 is also shown in FIGS. 12 and 13.

FIG. 11 shows the bottom view of the gasket 350. A plurality of pads 356 are provided on the bottom surface of the gasket 350. The pads 356 surround the through holes 354. The pads 356 can be oval or rectangular. The pads 356 extend in a radial direction. The pads 356 engage with the plugs shown at 360 in FIGS. 12 and 13 and prevent the cleaning fluid from flowing into the support structures 150 of the pedestal 100. The pads 356 also prevent the cleaning fluid from flowing over and towards the center of the top surface of the base portion 102 (i.e., the area covered by the dotted circle shown in FIG. 2).

FIG. 12 shows an example of a top view of the pedestal 100 with the gasket 350 sealing the groove 130, which is covered by the gasket 350. The top surface of the gasket 350 is visible in the view shown. The bottom surface of the gasket 350 is in contact with the top surface of the base portion 102 (i.e., the top surface of the plate 110) of the pedestal 100 and is not visible in the view shown. The top plate 300 of the fixture 200, which will be on the top surface of the pedestal 100, is omitted in the view to show how the gasket 350 seals the groove 130. The gasket 350 seals areas of the top surface of the base portion 102 of the pedestal 100 that are radially inwards and outwards from the gasket 350.

A plurality of plugs 360 (shown at 360-1, 360-2, 360-3, collectively the plugs 360) are inserted into the grooves 154 in the support structures 150 of the pedestal 100. The plugs 360 may be made of the same material as the gasket 350. When the top plate 300 with the gasket 350 is installed on the top surface of the pedestal 100, the inner ends of the plugs 360 engage with the gasket 350. The protrusions 334 on the bottom side of the top plate 300 (shown in FIG. 8) fit into the grooves 154 in the grooves 154 in the support structures 150 of the pedestal 100. Outer ends of the plugs 360 engage with inner ends of the protrusions 334. Thus, the gasket 350, the plugs 360, and the protrusions 334 seal the support structures 150 and prevent the cleaning fluid from flowing into the support structures 150 of the pedestal 100.

FIG. 13 shows a partial cross-sectional view of a portion of the top view of the pedestal 100 shown in FIG. 12. The view shows a cross-sectional view of the gasket 350. Elements shown in FIG. 13 that are already described above are not described again for brevity. Additional elements that are shown and that are not described above include fasteners 323 and a conduit 370. The fasteners 323 are used to fasten the metal ring 320 to the top plate 300 in the groove 321 on the edges of the top plate 300. The conduit 370 is attached to the holes 304 in the top plate 300 and the through holes 354 of the gasket 350 to supply the cleaning fluid to the groove 130. The conduit 370 is connected to the manifold assembly 220 attached to the top surface of the top plate 300. The conduit 370 and the manifold assembly 220 are described below in further detail with reference to FIG. 19.

### Lower Portion of Fixture

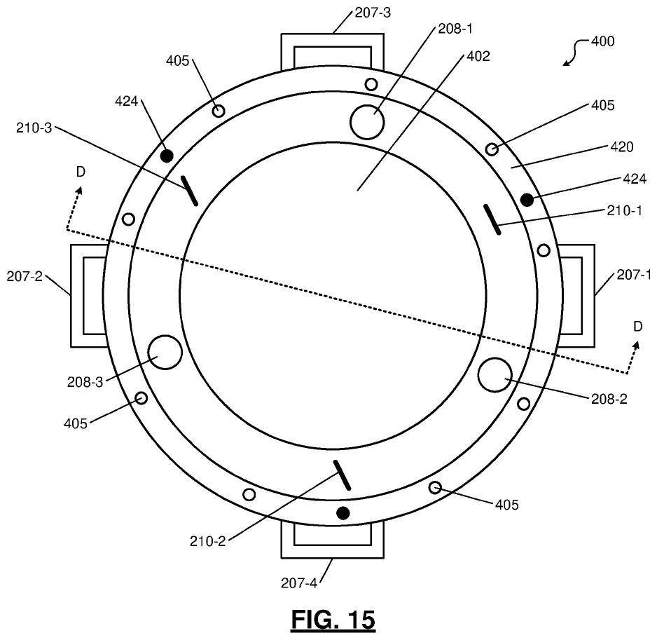

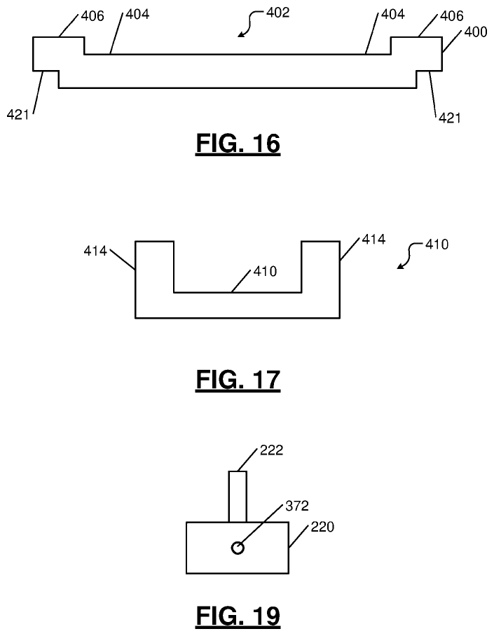

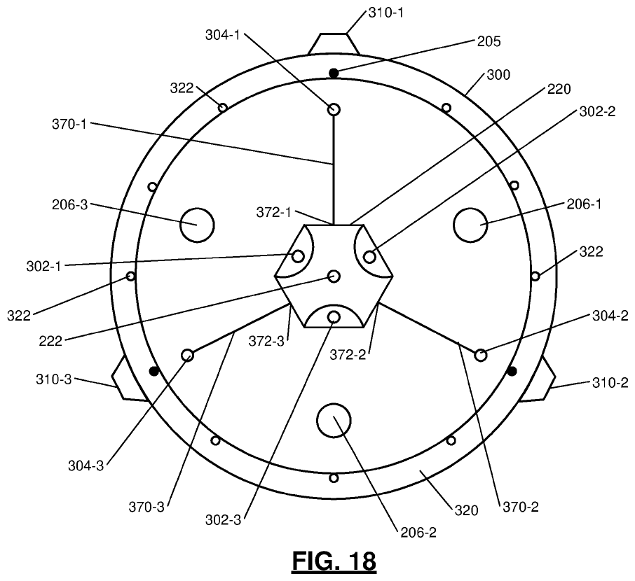

The lower portion 204 of the fixture 200 comprises a bottom plate 400, which is shown and described in detail with reference to FIGS. 14-17. FIGS. 14 and 15 show top and bottom views of the bottom plate 400, respectively. FIG. 16 shows a cross-sectional view of the bottom plate 400. FIG. 17 shows a cross-sectional view of a guiding structure of the bottom plate 400.

FIG. 14 shows an example of a top view of the bottom plate 400 of the fixture 200. The bottom plate 400 is also made of the same material as the top plate 300 of the fixture. The bottom plate 400 comprises the handles 207. The handles 207 extend radially from outer edges of the bottom plate 400. The utility of the handles 207 is already described above with reference to FIG. 6 and is therefore not described again for brevity.

The bottom plate 400 is annular and comprises a through hole (opening) 402 at the center of the bottom plate 400. The stem portion 104 of the pedestal 100 can pass through the through hole 402 when the pedestal 100 is clamped between the top plate 300 and the bottom plate 400 of the fixture 200. An inner diameter of the bottom plate 400 defines the through hole 402. The inner diameter of the bottom plate 400 is less than the outer diameter of the base portion 102 of the pedestal 100. An outer diameter of the bottom plate 400 is greater than the outer diameter of the base portion 102 of the pedestal 100.

The top surface of the bottom plate 400 comprises a groove 404 along the inner diameter of the bottom plate 400 and comprises a ridge 406 along an outer diameter of the bottom plate 400. The ridge 406 extends vertically upwards from an outer diameter of the groove 404. An outer diameter of the ridge 406 defines an outer diameter of the bottom plate 400. The ridge 406 comprises a plurality of through holes 405 to receive the fasteners 205 when the top plate 300 of the fixture 200 is clamped to the bottom plate 400 with the pedestal 100 clamped between the top and bottom plates 300, 400 of the fixture 200. The outer diameter of the groove 404 is greater than the outer diameter of the base portion 102 of the pedestal 100. Thus, when the pedestal 100 is arranged on the top surface of the bottom plate 400, the bottom surface of the base portion 102 (i.e., the bottom surface of the plate 114) of the pedestal 100 rests on the groove 404.

The top surface of the bottom plate 400 comprises a plurality of guiding structures 410-1, 410-2, 410-3 (collectively the guiding structures 410). The guiding structures 410 are installed on the ridge 406. A cross-sectional view of the guiding structure 410 is shown in FIG. 17. Each guiding structure 410 comprises a horizontal member 412 (shown in FIG. 17) that is attached to the ridge 406. The guiding structure 410 comprises a pair of vertical members 414 that extend vertically upwards from two ends of the horizontal member 412.

The vertical members 414 of the guiding structures 410 comprise holes 407. The ridge 406 of the bottom plate 400 comprises corresponding through holes. The guiding structures 410 are fastened to the ridge 406 using fasteners that pass through the holes 407 and the corresponding through holes in the ridge 406. When the pedestal 100 is arranged on the top side the bottom plate 400, the guiding structures 410 surround the support structures 150 of the pedestal 100. The bottom surfaces of the support structures 150 of the pedestal 100 rest of the horizontal members 412 of the guiding structures 410.

The bottom plate 400 comprises through holes 409 to install the hooks 210 from the bottom surface of the bottom plate 400 (shown in FIGS. 6 and 15). The utility of the hooks 210 is already described above with reference to FIG. 6 and is therefore not described again for brevity.

FIG. 15 shows an example of a bottom view of the bottom plate 400 of the fixture 200. Elements shown in FIG. 15 that are already described above are not described again for brevity. The feet 208 are similar to the feet 206. The feet 208 are attached to the bottom surface of the bottom plate 400. The utility of the feet 208 is already described above with reference to FIG. 6 and is therefore not described again for brevity.

A metal ring 420 is attached to the bottom surface of the bottom plate 400. The metal ring 420 is similar to the metal ring 320 attached to the top plate 300 of the fixture 200. Therefore, the metal ring 420 is not described in further detail for brevity. The bottom surface of the bottom plate 400 comprises a groove 421 (shown in FIG. 16) in which the metal ring 420 is installed using fasteners 424. The metal ring 420 and the bottom plate 400 comprise holes to receive the fasteners 424. The metal ring 420 comprises through holes that align with the through holes 405 in the bottom plate 400. The fasteners 205 (shown in FIG. 6) are inserted into the through holes 322 of the top plate 300 and the metal ring 320 and into the through holes 405 of the bottom plate 400 and the metal plate 420 to clamp the top plate 300 and the bottom plate 400 with the pedestal 100 clamped in the fixture 200.

FIG. 16 shows a cross-sectional view of the top plate 300 taken along the line D-D shown in FIGS. 14 and 15. The view is shown with the top surface of the bottom plate 400 on top and the bottom surface of the bottom plate 400 on the bottom. Since the elements of the bottom plate 400 shown in FIG. 16 are already described above, they are not described again for brevity.

FIG. 17 shows a cross-sectional view of the guiding structures 410 shown in FIG. 14. The cross-section is taken along the axis parallel to the vertical members 414 of the guiding structures 410. Since the elements of the guiding structures 410 shown in FIG. 17 are already described above, they are not described again for brevity.

### Manifold Assembly

FIGS. 18 and 19 show an example of the manifold assembly 220 shown in FIG. 6. FIG. 18 shows an example of a top view of a manifold assembly 220 and conduits 370 installed on the top surface of the top plate 300 of the fixture 200. FIG. 19 shows an example of a side view of the manifold assembly 220. In the views shown in FIGS. 18 and 19, the manifold assembly 220 is in the same position (orientation) as that shown in FIG. 6.

In FIGS. 18 and 19, the manifold assembly 220 comprises the inlet 222 (also shown and described above with reference to FIG. 6). A plurality of conduits 370-1, 370-2, 370-3 (collectively the conduits 370) are connected to the manifold assembly 220 at 372-1, 372-2, 372-3 (shown as 372 in FIG. 19), respectively. While the conduits 370 are shown schematically using straight lines, the conduits 370 comprise tubes that can be bent to route the conduits 370 (e.g., around the feet 206) as needed. The remaining structural and functional details of the manifold assembly 220 and the conduits 370 are already described above in detail and are therefore not described again for brevity.

### Adapter

FIG. 20 shows an example of a cross-sectional view of the adapter 230 shown in FIG. 6. In the view shown, the adapter 230 is shown in an inverted position (orientation) compared to the position (orientation) of the adapter 230 shown in FIG. 6. Accordingly, the base portion 102 of the pedestal 100 is under the stem portion 104 in the view shown. In the following description of the adapter 230, any directional terms that are used to describe the components of the adapter 230 are used with the adapter 230 oriented as shown in the view.

The adapter 230 generally comprises three components: a clamp 500, a first component 502, and a second component 504. The clamp 500 comprises two members (not visible in the view shown). The two members of the clamp 500 surround the conduits 122, 136. The two members are clamped together around the conduits 122, 136. Thus, the clamp 500 clamps and holds the conduits 122, 136 in a fixed position.

The first component 502 of the adapter 230 has a shape of a cup or a well (generally a U-shape). The first component 502 can be cylindrical or of any other shape. The second component 504 has a shape that corresponds to the shape of the first component. For example, when the first component 502 is cylindrical, the second component is also cylindrical.

When the first and second components 502, 504 are cylindrical, the first component 502 comprises a horizontal member 510 and a vertical member 512. The horizontal member 510 comprises a flat circular disc. The vertical member 512 is cylindrical and hollow. A first surface of the horizontal member 510 is attached to the stem portion 104 of the pedestal 100. The vertical member 512 extends perpendicularly from a second surface of the horizontal member 510. The vertical member 512 extends in a direction opposite to the stem portion 104 of the pedestal. A first end of the vertical member 512 is attached to the second surface of the horizontal member 510. A second end of the vertical member 512 extends perpendicularly to the horizontal member 510 defining a cavity 514 in the first component 502. Thus, the first component 502 is closed at a first end (i.e., at the end where the horizontal member 510 and the first end of the vertical member 512 are joined) and open at a second end (i.e., at a second end of the vertical member 512). The conduits 122, 136, 140 pass through the horizontal member 510 into the cavity 514 in the first component 502. The conduits 122 and 136 are clamped by the clamp 500 as described above.

The second component 504 of the adapter 230 is similar in shape to the first component 502. For example, the second component 504 is also cylindrical. The second component 504 comprises a horizontal member 520 and a vertical member 522. The horizontal member 520 is circular. The vertical member 522 is cylindrical and hollow. The vertical member 522 extends perpendicularly from a first surface of the horizontal member 520. A first end of the vertical member 522 is attached to the first surface of the horizontal member 520. A second end of the vertical member 522 extends perpendicularly to the horizontal member 520 defining a cavity 524 in the second component 504. Thus, the second component 504 is also closed at a first end (i.e., at the end where the horizontal member 520 and the first end of the vertical member 522 are joined) and open at a second end (i.e., at a second end of the vertical member 522).

The second component 504 comprises a cylindrical block 530. The cylindrical block 530 is solid. A diameter of the cylindrical block 530 is less than an inner diameter of the vertical member 522 of the second component 504. A first end of the cylindrical block 530 is attached to the first surface of the horizontal member 520. A second end of the cylindrical block 530 extends perpendicularly from the horizontal member 520 in the same direction as the vertical member 522. The second end of the cylindrical block 530 extends into the cavities 514, 524. The second end of the cylindrical block 530 extends up to the clamp 500.

The conduit 122, which is used for vacuum clamping and which is clamped by the clamp 500, extends through the clamp 500 into the cylindrical block 530. For example, the cylindrical block 530 comprises a shallow hole at second end of the cylindrical block 530. The conduit 122 extends and terminates into the shallow hole in the cylindrical block 530. Since the cylindrical block 530 is solid, the conduit 122 is sealed by the cylindrical block 530.

The cylindrical block 530 comprises a bore 532. A first end of the bore 532 is at the second end of the cylindrical block 530. The first end of the bore 532 is connected to the conduit 136, which is used to supply the edge gas and which is clamped by the clamp 500. A second end of the bore 532 is at a second surface of the horizontal member 520. The second end of bore 532 forms the inlet 232 (shown in FIG. 6) at the second surface of the horizontal member 520.

The first and second components 502, 504 are fitted together as follows. The inner diameter of the vertical member 522 of the second component 504 is equal to an outer diameter of the vertical member 512 of the first component 502. Thus, the vertical member 522 of the second component 504 slides over and around the vertical member 512 of the first component 502. The vertical members 512 and 522 of the first and second components 502, 504 are sealingly attached to each other. The cavities 514 and 524 in the first and second components 502, 504 define a single cavity in the adapter 230 when the first and second components 502, 504 are fitted together as described above.

When conduits 122 and 136 are clamped by the clamp 500 and the first and second components 502, 504 are fitted together, the conduit 122 plugs into the cylindrical block 530. The conduit 122 is sealed by the cylindrical block 530. The conduit 136 is connected to the bore 534 and to the inlet 232 by the bore.

The various components of the fixture 200 are assembled to clamp the pedestal 100 between the upper and lower portions 202, 204 of the fixture as follows. The bottom plate 400 is placed on the feet 208. The pedestal 100 is inserted in an upright position (base portion 102 up and stem portion 104 down) through the opening 402 in the bottom plate 400. The support structures 150 of the base portion 102 of the pedestal are aligned with the guiding structure 410 of the bottom plate 400 of the fixture 200. The base portion 102 rests on the groove 404 of the bottom plate 400. The gasket 350 is placed on the groove 130 on the top surface of the base portion 102 of the pedestal 100. The plugs 360 are inserted into the grooves 154 in the support structures 150 of the pedestal 100. The top plate 300 of the fixture 200, with the manifold assembly 220 and the conduits 370, is placed on the top surface of the base portion 102 of the pedestal 100. The protrusions 334 engage with the plugs 360 and the grooves 154 of the support structures 150 of the pedestal 100. The fasteners 205 are fastened to clamp the pedestal 100 between the top and bottom plates 300, 400 of the fixture 200.

When assembled as described above, the inlet 232 of the adapter 230, the bore 532 in the adapter 230, the conduit 136 in the stem portion 104 of the pedestal 100, the grooves 134, 132, 130 in the plate 112 of the base portion of the pedestal 100, the through holes 354 in the gasket 350 in the top plate 300 of the fixture 200, the holes 304 in the top plate 300 of the fixture 200, the conduits 370 attached to the holes 304, the manifold assembly 220, and the outlet 222 are in fluid communication with each other.

The assembly comprising the fixture 200 with the pedestal 100 clamped in the fixture 200 is transported by a gantry to the cleaning site and set up on the feet 206 in an inverted position. The adapter 230 is connected to the stem portion 104 of the pedestal 100. The cleaning fluid comprising a mixture of various acids and other chemicals is supplied from the inlet 232 and collected at the outlet 222. The mixture of acids and other chemicals is optimized to remove residual filler material trapped in the flow path of the edge gas (e.g., the grooves 134, 132, 130) when the acid mixture is supplied through the pedestal 100 using the fixture as described above. After the pedestal 100 is cleaned using the fixture 200 as above, the clean pedestal 100 can be used in the substrate processing system 10 of FIG. 1A. When the edge gas is supplied to the pedestal 100, the pedestal 100 does not eject contaminants with the flow of edge gas into the processing chamber 12.

The foregoing description is merely illustrative in nature and is not intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims.

It should be understood that one or more steps within a method may be executed in different order (or concurrently) without altering the principles of the present disclosure. Further, although each of the examples is described above as having certain features, any one or more of those features described with respect to any one of the examples of the disclosure can be implemented in and/or combined with features of any of the other examples, even if that combination is not explicitly described. In other words, the described examples are not mutually exclusive, and permutations of one or more examples with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate.

The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software).

Program instructions may be instructions communicated to the controller in the form of various individual settings (or program files), defining operational parameters for carrying out a particular process on or for a semiconductor wafer or to a system. The operational parameters may, in some examples, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process.

In some examples, a remote computer (e.g., a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control.

Thus, as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. A fixture for cleaning a pedestal of a substrate processing system, the fixture comprising:
a first portion of the fixture configured to couple to a first surface of a base portion of the pedestal, the first portion comprising a first port configured to fluidly connect with a plenum in the base portion of the pedestal;
a second portion of the fixture configured to couple to a second surface of the base portion of the pedestal;
at least one fastener configured to fasten the first and second portions of the fixture to clamp the base portion of the pedestal between the first and second portions of the fixture; and
an adapter configured to couple to a conduit in a stem portion of the pedestal, the adapter comprising a second port configured to fluidly connect with the plenum via the conduit.

2. The fixture of claim 1 wherein the first portion and the adapter are configured to circulate a cleaning fluid through the first and second ports and the plenum.

3. The fixture of claim 2 wherein the cleaning fluid comprises a mixture of acids.

4. The fixture of claim 1 wherein the first port is configured to receive a cleaning fluid that flows through the plenum and flows out of the second port.

5. The fixture of claim 1 wherein the second port is configured to receive a cleaning fluid that flows through the plenum and flows out of the first port.

6. The fixture of claim 1 further comprising an annular gasket disposed between the first portion and the first surface of the base portion of the pedestal, wherein the annular gasket is configured to seal areas on the first surface of the base portion of the pedestal that are radially inwards and outwards from the annular gasket.

7. The fixture of claim 1 wherein the adapter is configured to seal a second conduit in the stem portion of the pedestal provided to create vacuum on the first surface of the base portion of the pedestal.

8. The fixture of claim 1 wherein the first portion comprises:
a plate comprising a first surface and a second surface;
a manifold connected to the first surface of the plate and to the first port;
a plurality of conduits connected to the manifold; and
a gasket disposed between the second surface of the plate and the first surface of the base portion of the pedestal.

9. The fixture of claim 8 wherein:
the plate comprises an annular groove on the second surface of the plate;
the gasket is disposed in the annular groove;
the plate and the gasket comprise a plurality of through holes that are aligned with each other and with a groove of the plenum on the first surface of the base portion of the pedestal; and
the plurality of conduits is connected to the plurality of through holes in the plate, respectively.

10. The fixture of claim 9 wherein the annular groove and the gasket comprise alignment features configured to align the plurality of through holes of the plate and the gasket.

11. The fixture of claim 9 wherein the gasket is configured to seal areas on the first surface of the base portion of the pedestal that are radially inwards and outwards from the gasket.

12. The fixture of claim 9 further comprising a plurality of plugs configured to couple with a plurality of support structures provided on a periphery of the base portion of the pedestal to support a carrier ring, wherein:
the plate comprises a plurality of protrusions extending radially from outer edges of the plate to an outer diameter of the gasket;
the plurality of protrusions is configured to fit in the plurality of support structures, respectively; and
radially inner ends of the plurality of protrusions position the plurality of plugs to contact the outer diameter of the gasket and to seal the plurality of support structures.

13. The fixture of claim 12 wherein the gasket comprises a plurality of pads that surrounds the plurality of through holes of the gasket, respectively; that extends over the plurality of plugs, respectively; and that extends radially inwards from an inner diameter of the gasket beyond an inner diameter of the groove of the plenum on the first surface of the base portion of the pedestal.

14. The fixture of claim 8 further comprising a metal ring disposed on a periphery of the first surface of the plate wherein the fasteners passes through the metal ring.

15. The fixture of claim 8 wherein the plate comprises a plurality of feet attached to the first surface of the plate.

16. The fixture of claim 8 wherein the plate comprises a chemically resistant material.

17. The fixture of claim 1 wherein the second portion comprises an annular plate comprising:
an annular groove on a first surface of the annular plate along an inner diameter of the annular plate, an outer diameter of the annular groove being greater an outer diameter of the base portion of the pedestal, and an inner diameter of the annular groove being less than the outer diameter of the base portion of the pedestal; and
a ridge extending on the first surface of the annular plate from the outer diameter of the annular groove, the ridge comprising a plurality of through holes to receive the fasteners.

18. The fixture of claim 17 further comprising a plurality of guiding structures on the ridge to receive a plurality of support structures provided on a periphery of the base portion of the pedestal to support a carrier ring.

19. The fixture of claim 17 further comprising a metal ring disposed on a periphery of the second surface of the plate wherein the fastener passes through the metal ring.

20. The fixture of claim 17 further comprising a plurality of handles on a periphery of the plate.

21. The fixture of claim 17 wherein the plate comprises a plurality of feet attached to the second surface of the plate.

22. The fixture of claim 17 further comprising a plurality of hooks attached to the second surface of the plate.

23. The fixture of claim 17 wherein the plate comprises a chemically resistant material.

24. The fixture of claim 1 wherein the adapter comprises:
a clamp that clamps the conduit and a second conduit disposed in the stem portion of the pedestal;
a first component comprising a first circular member configured to attach to the stem portion of the pedestal and a first cylindrical member that extends from the first circular member; and
a second component comprising a second circular member, a second cylindrical member that extends from the second circular member and that sealingly attaches to the first cylindrical member, and a solid cylindrical member that extends from the second circular member within the second cylindrical member to the clamp and that seals the second conduit.

25. The fixture of claim 24 wherein the solid cylindrical member comprises a bore comprising a first end connected to the conduit in the clamp and a second end defining the second port.
